(19) United States
(12) Patent Application Publication
(10) Pub. No.: US 2016/0248233 A1
(43) Pub. Date: Aug. 25, 2016

(54) Precision Mounting System for Wall Mounted Electrical Enclosure

(71) Applicant: Crenlo Cab Products, Inc., Rochester, MN (US)

(72) Inventors: Steven Roy Leidig, Rochester, MN (US); Eric John Ziemer, Rochester, MN (US); Richard Lee Grant, Rochester, MN (US)

(73) Assignee: Crenlo Cab Products, Inc., Rochester, MN (US)

(21) Appl. No.: 15/048,610

(22) Filed: Feb. 19, 2016

Related U.S. Application Data
(60) Provisional application No. 62/118,972, filed on Feb. 20, 2015.

(51) Int. Cl. H02B 1/40; H05K 5/02

(52) U.S. Cl. CPC H02B 1/40; H05K 5/0217

(57) ABSTRACT

An enclosure adapted to be mounted on a generally vertical surface such as a wall. The enclosure has housing with a first opening in one of its sides and a second opening in another of its sides. The side with the second opening has a first mounting member and a second mounting member. In use, a first bracket is combined with the vertical surface by fastening members. The first bracket has an opening or slot along its top surface adapted to receive the first mounting member of the enclosure housing. A second bracket, which may be similar to the first bracket, is adapted to be inserted into the housing through the first opening after the enclosure housing is hung on the first bracket. The second bracket is secured to the vertical surface so that it receives the second mounting member which prevents the housing from being lifted off of the first bracket.

This application is based upon U.S. Provisional Application Ser. No. 62/118,972 filed Feb. 20, 2015, the complete disclosure of which is hereby expressly incorporated by this reference.

### BACKGROUND

This invention relates to the field of enclosures, particularly electrical enclosures which are mounted on a vertical surface such as a wall and require strong, precise, and secure mounting. Wall mounted electrical enclosures have changed over time as the electronics populated within them has evolved. There are many systems for mounting enclosures to vertical surfaces. One existing system uses a template for the placement of screw anchors to match the template pattern of mounting holes on the enclosure. Often this template is on the packaging of the enclosure. The template approach produces several installation problems. First, the template is often mistakenly discarded as part of the packaging. Second, it is difficult to level the paper or corrugate template accurately. Improper leveling puts uneven loading on the wall anchors and also causes any hinged section, door, or panel to swing open or closed due to gravity. Further, it can be difficult to hold the enclosure at the proper height against the wall while simultaneously securing the enclosure to the wall using fasteners.

Another existing mounting system includes an enclosure which is manufactured with keyhole shaped cut outs adapted to receive fasteners. The fasteners are loosely affixed to the wall then the enclosure is hung on the fasteners before tightening the fasteners. While this is convenient, installation of the anchors ahead of time leaves the fasteners bearing the weight load before they are fully tightened. This is a dangerous practice since the fasteners are not fully secured to the wall. Even when safety is addressed, the direction of the fastener may be impacted by the premature loading while it is being tightened leading to less than optimal holding or pull-out strength of the fastener. There is also potential to damage the threads of the fasteners or the enclosure when driven in under such shear loads. Electrical enclosures are often designed to house rack mount equipment of 19, 24, or 30 inch widths. Depending on where the keyholes are located, it is often difficult to anchor into the studs properly since typical building code stud widths are approximately 16 to 24 inches on center. Assuming the fastener is targeting a wall stud, the position of round openings or keyhole mounts does not allow adjustment in the horizontal (X) direction making proper anchoring to multiple studs difficult. Finally, lifting a medium to large sized populated enclosure and fitting the alignment to the keyholes is difficult for an installer as the keyholes are two to four relatively small targets.

Alternatively, some wall mounted electrical enclosures utilize mounting holes/fasteners that are on the outside of the enclosure. These carry with them some of the shortcomings of the previously described systems. In addition, the external mounting holes/fasteners are exposed and therefore unsecured. In other words, anyone could remove the enclosure from the wall and gain access to the internal components using only a wrench or screwdriver to remove the external fasteners.

There is therefore a need for an improved wall mountable enclosure which overcomes these and other deficiencies in the prior art.

### SUMMARY

One aspect of the invention includes an enclosure system adapted to be mounted on a generally vertical surface such as a wall. The system includes an enclosure housing having a first opening in one of its walls and a second opening in another of its walls. The wall with the second opening has a first mounting member such as a top lip and a second mounting member such as a bottom lip. Mounting hardware is used to secure the housing to the vertical surface. In one embodiment, the mounting hardware includes a first bracket and a locking member such as a second bracket. The first bracket is adapted to be combined with the vertical surface by fasteners such as screws, bolts, or nails. The bracket has a gap, opening, or slot (collectively an “opening”) created between it and the wall. The opening is adapted to receive the first mounting member of the wall with the second opening of the enclosure housing. In other words, the housing is hung on the first bracket so that the vertical surface (e.g., wall) covers the second opening of the housing by effectively forming the rear wall of the enclosure. A second bracket, which may be similar to the first bracket, is adapted to be inserted through the first opening after the enclosure housing is hung on the first bracket. The second bracket is positioned upside down relative to the first bracket (so its opening is facing downward). The opening created between the second bracket and the wall is adapted to receive the second mounting member of the wall with the second opening of the enclosure housing and be fastened to the vertical surface by fasteners. In another embodiment the mounting hardware includes a first bracket (as described above) and the locking member is one or more fasteners which are inserted through openings in the rear wall of the housing and into the vertical service (i.e., these fasteners are used as the locking member instead of a second bracket). In both embodiments, the weight of the housing hangs from the first bracket and the locking member (second bracket and/or fasteners) prevents the housing from being lifted off of the first bracket by preventing the housing from moving in an upward direction. In both embodiments the mounting hardware is encapsulated by and only accessible from inside the housing to help prevent unauthorized access to or removal of the enclosure.

In another aspect of the invention, a kit for a wall mounted enclosure which includes the components described in the previous paragraph.

In another aspect of the invention, a method for mounting a wall mounted enclosure. The method includes taking an enclosure housing having a first opening in one of its walls and a second opening in another of its walls. The second opening has a first mounting member such as top lip and a second mounting member such as bottom lip. The method further includes using mounting hardware to secure the enclosure housing to a vertical surface. In one embodiment the mounting hardware includes a first bracket and a locking member such as a second bracket. A gap or opening is created between each bracket and the wall. The opening is adapted to receive one of the first mounting member and the second mounting member. The first bracket is secured to the vertical surface using fasteners then the enclosure housing is hung on the first bracket by positioning the first mounting member in the first bracket's opening (i.e., between the bracket and the wall). Once hung on the top bracket, the second bracket is inserted into the enclosure housing through the second opening and then secured to the vertical surface so the second mounting member is received into the opening between the second bracket and the wall. In another embodiment the mounting hardware includes a first bracket (as described above) and the locking member is one or more fasteners which are inserted through openings in the rear wall of the housing and into the vertical service (the locking member is fasteners instead of a second bracket). Once installed, the enclosure housing is hung on the wall with the locking member (bottom bracket and/or fasteners) preventing it from being lifted off of the top bracket. In some embodiments there is a door on the housing for selectively opening and closing the first opening. In its closed position the door may be locked to prevent unauthorized access to the inside of the enclosure through the first opening. All mounting hardware (i.e., the brackets and/or fasteners) is covered by the housing so that it is only accessible from the inside of the enclosure housing.

### BRIEF DESCRIPTION OF THE DRAWINGS

FIG. 1 is a perspective view of an embodiment of the enclosure.

FIG. 2 is a perspective view showing the enclosure housing being hung on the first bracket after the first bracket is secured to the vertical surface.

FIG. 3 is a perspective view showing the second bracket being inserted into the enclosure housing through the first opening so it can be secured to the vertical surface after the enclosure is hung from the first bracket.

FIG. 4 is a perspective view of a bracket.

FIG. 5 is a section view showing the first bracket and the second bracket secured to a vertical surface where the housing has been removed for clarity.

FIG. 6 is a section view showing the enclosure housing secured to the vertical surface by the first bracket and the second bracket.

FIG. 7 is a perspective view of an alternate embodiment wherein the housing is articulated and the housing is secured to the vertical surface by a first bracket and fasteners (but no second bracket).

FIG. 8 is another perspective view of the embodiment shown in FIG. 7.

### DETAILED DESCRIPTION

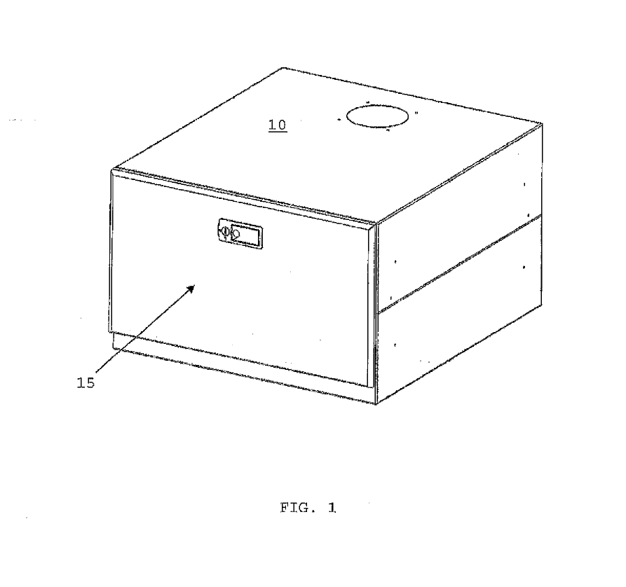

One embodiment of the invention includes an enclosure system adapted to be mounted on a generally vertical surface 13, such as a wall. FIG. 1 shows an embodiment of the enclosure wherein the enclosure comprises a housing 10 having a door 15 in one of the enclosure's walls which is adapted to be open and closed. In its closed position, the door 15 may be locked by any suitable locking means to prevent unauthorized access to the internal cavity of the housing 10.

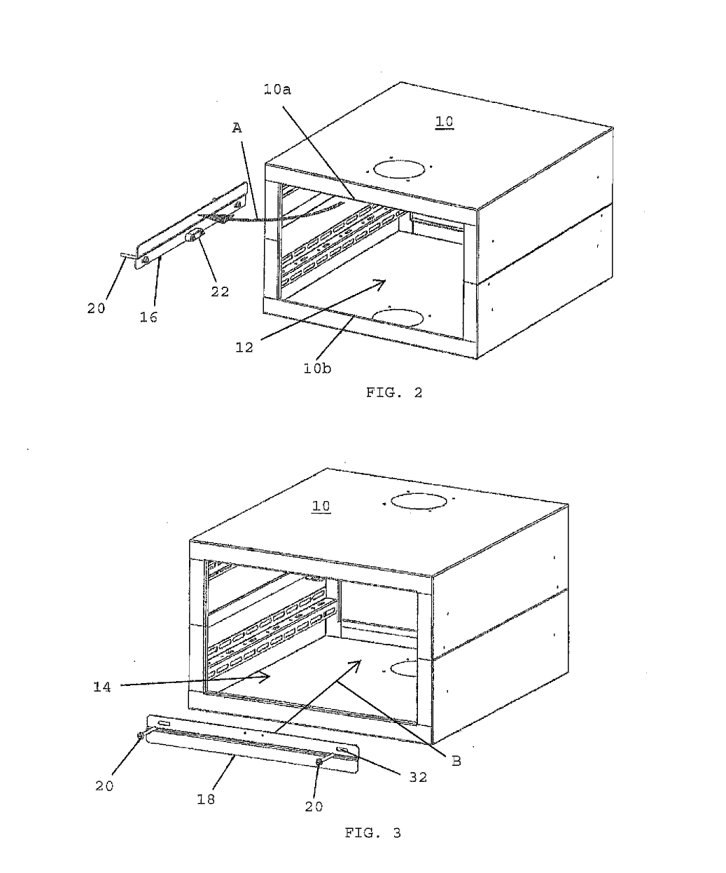

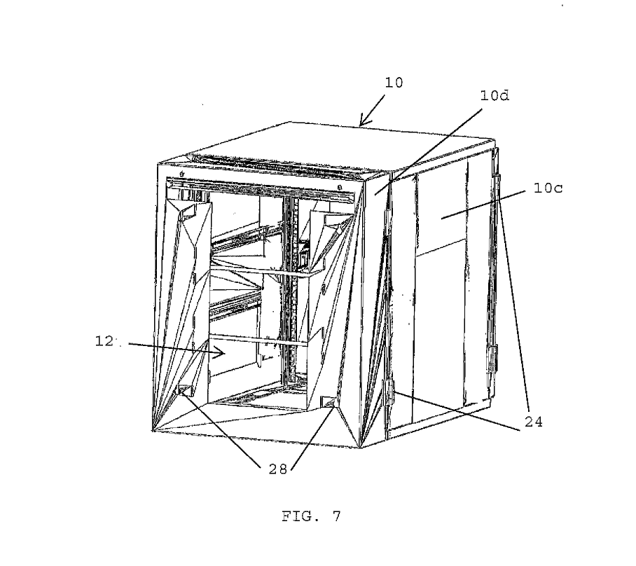

FIGS. 2 and 3 show additional views of the housing 10. FIG. 2 shows an opening 12 in one of the walls. As shown, this opening 12 is in the rear of the housing (if the front is considered the side with the door 15), however, it may also be in one of the other top, bottom, or side walls. As described below in more detail, the opening 12 faces the vertical surface (e.g., wall) 13 after the enclosure is mounted so that the vertical surface 13 covers the opening 12 and prevents entry into the internal cavity of the housing 10. Near the top side of the opening 12, the housing 10 forms an upper mounting member 10a such as a lip and near the bottom side of the opening 12 the housing 10 forms a lower mounting member 10b such as lip. The mounting members 10a, 10b are generally structural members that form part of the rear housing wall and are adapted to be received by openings 17, 19 created between the brackets 16, 18 and the vertical surface 13 (described below). The mounting members 10a, 10b may protrude outward from a portion of the housing 10 to form a lip or tongue. As shown generally in FIGS. 2 and 6, in one embodiment the mounting members 10a, 10b are part of the rear wall of the housing 10. The housing 10 has a top surface and bottom surface, each of which terminate at a rear edge where the housing 10 turns generally ninety degrees to form the mounting members 10a, 10b as part of the rear wall of the housing 10. The mounting members 10a, 10b stop where the opening 12 begins.

FIG. 3 shows an opening 14 in one of the other walls of the housing. As shown, this opening 14 is in the front (the side with the door 15), however, it may also be in one of the other top, bottom, or side walls. The door 15 is not shown in FIG. 3, however, the door 15 is typically combined with the housing 10 (as shown in FIGS. 1 and 8) to selectively cover opening 14 and prevent unauthorized access to the internal cavity of the housing 10.

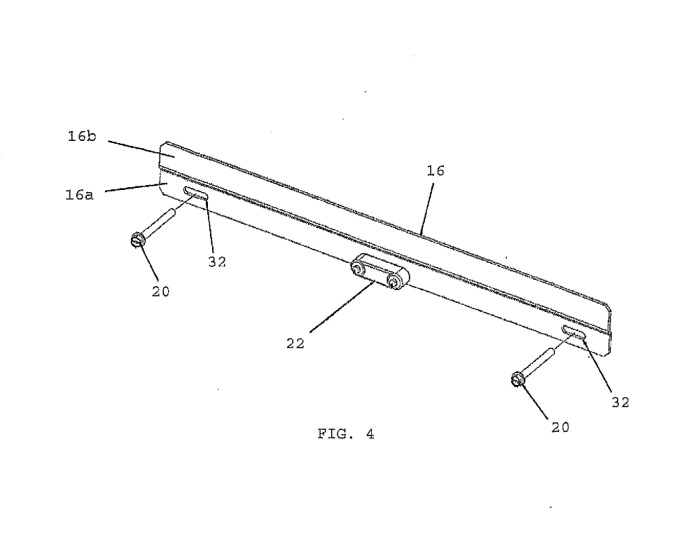

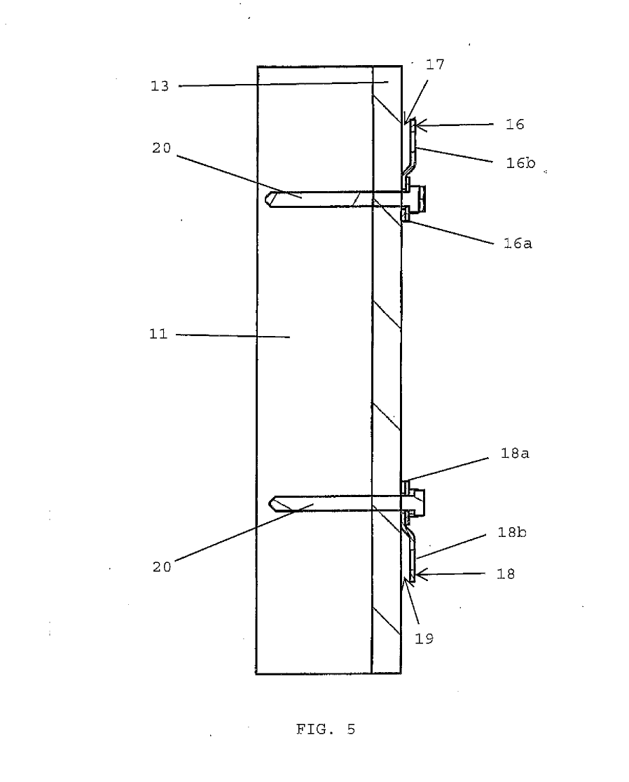

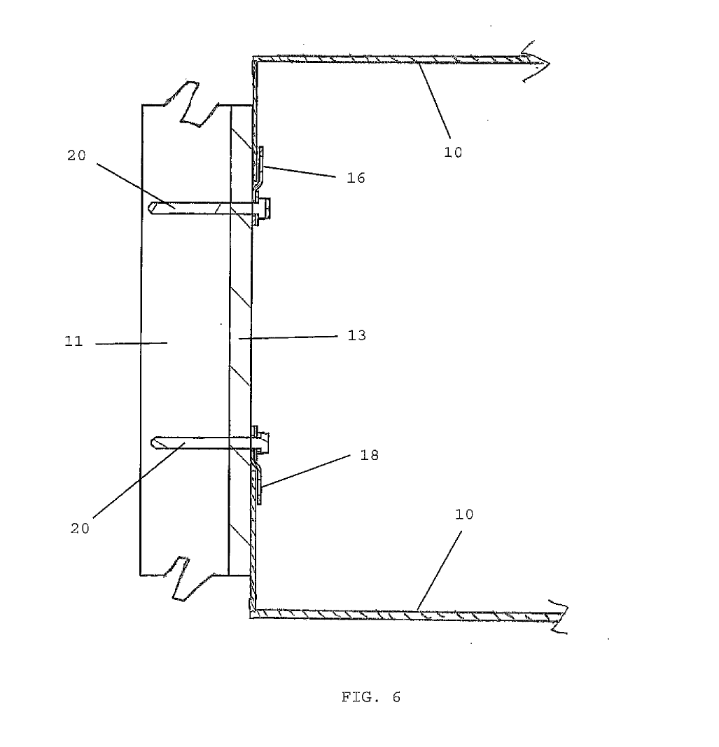

The system further includes mounting hardware for securing the housing 10 to the vertical surface 13. In the embodiment shown in FIGS. 2-6, the mounting hardware includes a first bracket 16 and a locking member. The locking member helps secure the housing 10 to the first bracket 16 so the housing 10 is not purposefully or inadvertently lifted off of the bracket 16. In one embodiment the locking member is a second bracket 18. FIG. 4 shows an exemplary bracket 16, 18. In some embodiments the first bracket 16 and second bracket 18 have the same general shape, so the bracket shown in FIG. 4 may be either the first bracket 16 or the second bracket 18. In some embodiments, however, the second bracket 18 is different from the first bracket 16 because the second bracket 18 does not include a level 22. FIG. 5 shows a section view of the two brackets 16, 18 mounted to a vertical surface 13. As described below, in practice the second bracket 18 is not secured to the vertical surface 13 until after the housing 10 is hung on the first bracket 16, however, the housing 10 has been removed from FIG. 5 to more clearly show the detail of the brackets 16, 18. In one embodiment each bracket 16, 18 has two portions offset from each other so that the two portions are in different planes. The first portion 16a, 18a of each bracket 16, 18 is a wall engaging portion and the second portion 16b, 18b of each bracket 16, 18 is the housing 10 engaging portion. The second portion 16b, 18b of the bracket 16, 18 extends outward from the wall 13 to create a gap or opening 17, 19 between each second portion 16b, 18b and the vertical surface 13. The opening 17 created between the first bracket 16 and the vertical surface 13 is adapted to receive the first mounting member 10a of the housing 10 and the opening 19 formed between the second bracket 18 and the wall 13 is adapted to receive the second mounting member 10b of the housing 10. To form the openings 17, 19, the two bracket portions may be offset and parallel to each other such that they generally form a “Z” shape. In an alternate embodiment the two portions may intersect each other at some angle such as a “V” shape. In yet another embodiment, the two portions need not be planer, they may instead be curved so that they form an “S” shape.

As shown in FIG. 4, the wall engaging portions 16a, 18a have at least one opening 32 adapted to receive fasteners 20 for securing each bracket 16, 18 to the generally vertical surface 13. Any suitable fastener 20 may be used, including screws, bolts, and nails. In one embodiment the openings 32 in the first portion 16a, 18a of the bracket 16, 18 are elongated along their horizontal (x) axis to create a slot. This allows the brackets 16, 18 to be adjusted along the horizontal (x) axis relative to the fasteners 20 to a desired position on the wall 13 regardless of where the studs 11 are located. In other words, the brackets 16, 18 may be adjusted horizontally after the fasteners 20 are loosely secured to the studs 11. Once the brackets 16, 18 are properly positioned along the horizontal (x) axis, the fasteners 20 are fully secured to the studs 11.

FIG. 6 shows the housing 10 mounted to the vertical surface 13 by the brackets 16, 18. The second portions 16b, 18b of each bracket 16, 18 extend a predetermined distance away from the tip of each mounting member 10a, 10b (e.g., toward the corner of the housing 10) to overlap with and help support the housing 10. As shown, the first/upper bracket 16 bears the weight of the housing 10 and second/lower bracket 18 does not bear any of the housing's 10 weight. Instead, the lower bracket 18 prevents the housing 10 from being lifted off of the upper bracket 16, as described below in more detail. However, the second/lower bracket 18 may support the housing 10 and be attached to the vertical surface 13 first if the orientation of the bracket 18 is reversed (so the opening 19 faces upward) and the lower mounting member 10b is configured to be received into the opening 19 (e.g., protrude downward instead of upward).

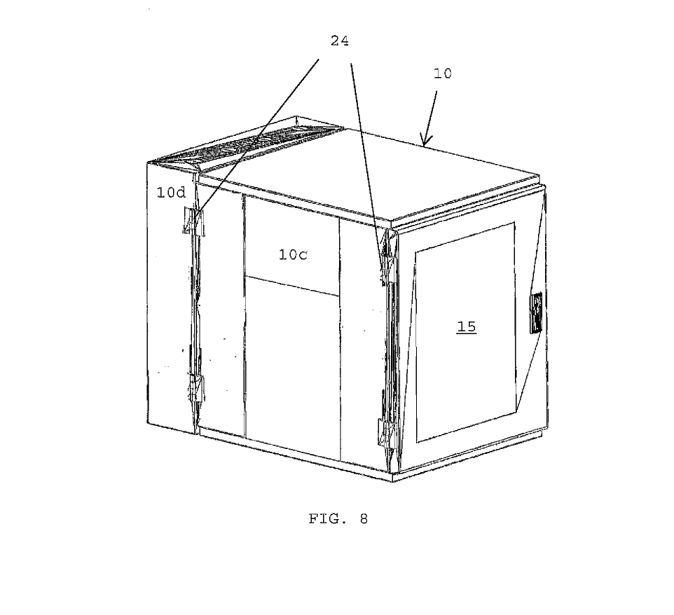

FIGS. 7 and 8 show an alternate embodiment of the enclosure housing 10. The embodiment shown in FIGS. 7 and 8 includes features which are beneficial for larger and heavier enclosures; however, these features may also be used alone or in combination with the embodiments described above. This embodiment includes a door 15 as described above to selectively open the front of the enclosure and access the enclosure through opening 14. The door 15 is attached to the housing 10 via hinges 24. The housing 10 shown in FIGS. 7 and 8 is jointed or articulated between its front and back to create a housing first portion 10c and a housing second portion 10d. The two portions 10c, 10d are attached by a hinge 24 or other suitable means to allow the first portion 10c to move or pivot relative to the second portion 10d. This feature is beneficial, especially in larger housings 10, because it allows the user easy access to the rear of the housing 10 by moving or pivoting the first portion 10c to an open position after the housing second portion 10d has been secured to the vertical surface 13. In this embodiment the enclosure preferably includes two locking mechanisms. One locking mechanism is used to selectively lock the door 15 in its closed position and the other locking mechanism is used to selectively lock the first portions 10c in its closed position relative to the second portion 10d to prevent unauthorized access to the inside of the housing 10.

The embodiment shown in FIGS. 7 and 8 uses mounting hardware that is different from the mounting hardware described above. Again, this alternate embodiment is useful for larger and heavier enclosures, however, it may be used with an enclosure or any size or weight. The mounting hardware in this alternate embodiment includes a first bracket 16 that is secured to the vertical surface 13 then the mounting member 10a of the housing 10 is hung on the bracket 16 as described in the previous embodiment. This alternate embodiment does not necessarily include a second bracket 18 as the locking member (in some embodiments the locking member may include a second bracket 18 in addition to the fasteners 20 used in this alternate embodiment). Instead, as shown in FIG. 7, the rear wall of the enclosure 10 includes at least one opening 28 adapted to receive a fastener 20 as the locking member. The fasteners 20 serve several functions. First, they help prevent the housing 10 from being lifted off of the first bracket 16. Second, they are secured to the wall 13 (preferably into a stud 11) to help bear some of the load of the housing 10 along with the first bracket 16.

Another embodiment of the invention is a kit for a wall mounted enclosure which includes the components described above.

Another embodiment of the invention includes a method for mounting a wall mounted enclosure. The method includes taking an enclosure housing 10 having a first opening 14 in one of its walls and a second opening 12 in another of its walls. The second opening 12 has first mounting member 10a such as a top lip and a second mounting member 10b such as a bottom lip. The method further includes securing a first bracket 16 (as described above) to a generally vertical surface 13 using fasteners 20.

The bracket 16 should be positioned at a location where it can be safely hung (such as by securing fasteners 20 into studs 11), where it is generally level, and also where the housing 10 will cover any openings or wires coming from the vertical surface 13. In some embodiments the bracket 16 includes a level 22 for leveling the bracket 16 to help ensure even support of the housing 10 by the bracket 16. The arrow A in FIG. 2 shows the housing 10 being hung on the bracket 16 so the first mounting surface 10a is received by the opening 17 created between the wall 13 and the bracket 16. A second bracket 18 is secured to the wall 13 so that the second mounting surface 10b of the housing 10 is received by the opening 19 formed between the second bracket 18 and the wall 13. In one embodiment, the first bracket 16 is similar to the second bracket 18, but the second bracket 18 is installed upside down so that its opening 19 faces the opposite direction (downward) to properly engaged the second mounting surface 10b. Further, the second bracket 18 does not need to include a level since the first bracket 16 will determine whether the housing 10 is level. As shown in the figures, the first bracket 16 is positioned above the second bracket 18 and combined with the vertical surface 13 before the second bracket 18. However, the second/lower bracket 18 may be secured to the vertical surface 13 first if its orientation is flipped so that its opening 19 faces upward and the corresponding lower mounting member 10b is configured to be received into the opening 19 (e.g., protrudes downward instead of upward) to support the load of the housing 10. In other words, the first bracket secured to the vertical surface 13 must be able to support the weight of the housing 10 until the second bracket is secured to the vertical surface 13 and this does not necessarily require the top bracket to be hung first.

The arrow B in FIG. 3 shows the second bracket 18 being inserted through the housing's 10 first opening 14 in order to secure the second bracket 18 to the wall 13 from inside the housing 10. The housing 10 is now hung on the wall 13 as shown in FIG. 6 with the second bracket 18 preventing it from being lifted off of the first bracket 16. In some embodiments there is a door 15 combined with the housing 10 to selectively open and close the first opening 14. The door 15 may be locked to prevent unauthorized access to the inside of the enclosure.

After installation is complete, both the first bracket 16 and second bracket 18 are completely housed internal to the housing 10 and therefore secure from external tampering. In some embodiments there may be portions of the brackets 16, 18 accessible from outside the housing 10, however, the fasteners 20 are all internal to the housing 10 to prevent one or both of the brackets 16, 18 from being removed from the vertical surface 13. The sequence of securing the first bracket 16 to the wall 13 then hanging the housing 10 on the first bracket 16 also makes it possible for a single installer to install medium and large enclosures safely. Leveling and proper anchoring are important for maximum payload distribution; these features of the invention are thus improved by mounting the bracket 16 before hanging the housing 10.

FIGS. 7 and 8 show an embodiment where an alternate mounting method is used. This alternate embodiment is similar to the method described above except the locking member is fasteners 20 instead of a second bracket 18. The fasteners 20 are received by openings 28 in the rear of the housing 10. Similar to the second bracket 18, the fasteners 20 in the alternate embodiment help prevent the housing 10 from being lifted off of the upper bracket 16. In addition, the fasteners 20 are secured to the wall 13 (preferably into a stud 11) so they are able to help bear some of the load of the housing 10.

Having thus described the invention in connection with the preferred embodiments thereof, it will be evident to those skilled in the art that various revisions can be made to the preferred embodiments described herein without departing from the spirit and scope of the invention. It is my intention, however, that all such revisions and modifications that are evident to those skilled in the art will be included with in the scope of the following claims.

What is claimed is as follows:

1. An enclosure mounting system comprising:
a housing having a first side with a opening therein and a second side with an opening therein, wherein the second side of the housing further comprises a first mounting member and a second mounting member;
a first bracket secured to a vertical surface with a first fastener, wherein the first bracket has a first portion spaced apart from a second portion to create an opening between the second portion and the vertical surface, said first mounting member of the housing received into the opening;
a locking member secured to the vertical surface with a second fastener, said locking member engaged with the second mounting member to prevent the housing from being lifted off of the first bracket;
wherein the first fastener and the second fastener are enclosed by the housing.

2. The system of claim 1 further comprising a door combined with the housing for selectively closing the opening in the first side.

3. The system of claim 1 wherein the locking member is a second bracket having a first portion spaced apart from a second portion to create an opening between the second portion and the vertical surface, said second mounting member received into the opening.

4. The system of claim 1 wherein the locking member is the second fastener.

5. The system of claim 4 wherein the second mounting member includes an opening and the second fastener is received by the opening.

6. The system of claim 1 wherein the housing includes a first portion movable relative to a second portion.

7. The system of claim 6 wherein the housing first portion pivots relative to the housing second portion.

8. The system of claim 1 wherein the first bracket includes a level.

9. A enclosure mounting kit comprising:
a housing having a first side with a opening therein and a second side with an opening therein, wherein the second side of the housing further comprises a first mounting member and a second mounting member;
a first bracket adapted to be secured to a vertical surface by a first fastener, wherein upon attachment to the vertical surface the first bracket has a first portion spaced apart from a second portion to create an opening between the second portion and the vertical surface adapted to receive the first mounting surface;
a locking member adapted to engage the second mounting member with a second fastener to prevent the housing from being lifted off of the first bracket.

10. The kit of claim 9 further comprising a door combined with the housing for selectively closing the opening in the first side.

11. The kit of claim 9 wherein the locking member is a second bracket having a first portion spaced apart from a second portion to create an opening between the second portion and the vertical surface adapted to receive the second mounting member.

12. The system of claim 9 wherein the locking member is the second fastener.

13. The kit of claim 12 wherein the second mounting surface includes an opening and the second fastener is received by the opening as it is secured to the vertical surface.

14. A method for mounting an enclosure to a vertical surface comprising:
taking a housing having a first side with a opening therein and a second side with an opening therein, wherein the second side includes a first mounting member and a second mounting member;
securing a first bracket to the vertical surface using a first fastener, wherein the first bracket includes a first portion spaced apart from a second portion to create an opening between the first portion and the vertical surface;
hanging the housing on the first bracket so that the first mounting member is received by the opening between the first portion and the vertical surface;
inserting a locking member through the opening in the first side and securing the locking member to the vertical surface using a second fastener;
wherein the first fastener and the second fastener are enclosed by the housing.

15. The method of claim 14 wherein the locking member is a second bracket having a first portion spaced apart from a second portion to create an opening between the second portion, and the method further comprises securing the second bracket to the vertical surface so that the second mounting member is received by the opening.

16. The method of claim 14 wherein the locking member is the second fastener.

17. The method of claim 16 wherein the second mounting member includes an opening and the second fastener is received by the opening as it is secured to the vertical surface.

18. The method of claim 14 wherein the housing further comprises a door and the method further comprises closing and locking the door after the locking member is secured to the vertical surface.
